(19) United States
(12) Patent Application Publication
(10) Pub. No.: US 2025/0208180 A1
(43) Pub. Date: Jun. 26, 2025

(54) MEASURING ARRANGEMENT AND MEASURING METHOD FOR MEASURING A LOOP IMPEDANCE IN AN UNGROUNDED POWER SUPPLY SYSTEM

(71) Applicant: Bender GmbH & Co. KG, Gruenberg (DE)

(72) Inventor: Julian Reitz, Gruenberg (DE)

(21) Appl. No.: 18/989,186

(22) Filed: Dec. 20, 2024

(30) Foreign Application Priority Data
Dec. 20, 2023 (DE) 10 2023 136 029.9

(51) Int. Cl. G01R 27/16

(52) U.S. Cl. CPC G01R 27/16

(57) ABSTRACT

A measuring arrangement and method are for measuring a loop impedance of a residual current loop of an active and protective conductor in an ungrounded power supply system. A device connected to a consumer point measures a conductor-to-ground voltage and computes loop impedance. An insulation monitoring device determines the insulation resistance in the system via a grounding device between the active and protective conductors on the feeding side. This grounding device selectively overrides one of the active conductors according to the control information of the measuring device via the communication channel and forms a residual current loop with impedance measured by interacting with the extended measuring device on the consumer side. Control information generated by the measuring device is telecommunicated to the grounding device. An insulation monitoring device equipped therewith may conduct a measurement of the loop impedance in the ungrounded power supply system in addition to insulation monitoring.

This application claims priority to German Patent Application No. 10 2023 136 029.9 filed on Dec. 20, 2023, the disclosures of which are hereby incorporated by reference.

### TECHNICAL FIELD

The invention relates to a measuring arrangement and a measuring method for measuring a loop impedance of a residual current loop formed by an active conductor and a protective conductor in an ungrounded power supply system, the measuring arrangement having a measuring device connected to a consumer point and serving to measure a conductor-to-ground voltage and to calculate the loop impedance.

Furthermore, the invention relates to an insulation monitoring device for determining the insulation resistance in an ungrounded power supply system.

### BACKGROUND

The loop impedance represents the total resistance of all impedances in the residual current loop and is used to determine the short-circuit current which can be caused by an insulation fault, for example, if an active conductor makes unintentional contact with the protective conductor in an item of electrical equipment. The loop impedance must be as low as possible for the short-circuit current to reach the tripping current of an overcurrent protective device.

The measurement of the loop impedance during initial and periodic testing of electrical systems is not only prescribed by standards in accordance with DIN VDE 0100-600 (IEC 60364-6), but is also an important measure for reasons of electrical safety and fire protection.

Special measuring devices are available on the market in order to be able to conduct this type of measurement in power supply systems. This measuring function is often also part of so-called installation testers, which cover further standard tests.

The state of the art is based on the standard DIN EN 61557-3 (IEC 61557-3), which describes the requirements for measuring devices for measuring the loop impedance (loop measuring device) which use the voltage reduction method. In the scope of this method, the conductor-to-ground voltage is measured at the measuring point (consumer point) in the unloaded case U₀ (open-circuit voltage) and in the resistively loaded case U₁. In the loaded case, the conductor-to-ground voltage decreases slightly due to the existing loop impedance Zₛ. Using the two voltage values U₀, U₁ and the knowledge of the load resistance R₁ used, the value of the loop impedance Zₛ can be calculated (see also FIG. 1):

$${Z}_{s} = \vert {R}_{1} ( \frac{{\underline{U}}_{0}}{{\underline{U}}_{1}} ) - 1 \vert$$

The voltage values U₀, U₁ must be registered as complex values, i.e., according to magnitude and phase, in order to be able to compute the loop impedance Zₛ correctly in terms of magnitude.

All (complex) resistances in the fault loop, such as the resistance of the protective conductor PE, the terminal points, the fuses and the impedance of a transformer winding, are included in the loop impedance Zₛ.

While the loop measurements in grounded systems can be conducted directly at the consumer point, for example a socket outlet, without further circuitry interventions, special technical measures are required for testing in ungrounded power supply systems, also known as IT systems (French: Isolé Terre—IT), in contrast.

For in this type of power supply system, the active parts of the IT network are isolated from the ground potential-insulated against ground. The bodies (conductive housings) of the consumers connected to the IT network are connected individually or collectively to the ground potential by means of the protective conductor and are therefore grounded.

The advantage of the ungrounded power supply system is that in the event of an insulation fault (first fault), such as a ground fault or a body fault, the function of the connected consumers is not impaired, as a closed residual current loop cannot form between an active conductor of the IT system and ground due to the ideally infinitely large impedance value. This inherent safety means that a continuous power supply to the consumers fed by the ungrounded power supply system can be guaranteed even if a first insulation fault occurs. This type of system is therefore used in medical applications in particular.

To measure the loop impedance of a residual current loop formed by an active conductor and a protective conductor in the ungrounded power supply system, an active conductor must first be grounded in the direct vicinity of the feeding point of the line voltage—the line transformer in AC systems—in order to cause a residual current loop in conjunction with a measuring device connected to the consumer point on the load side.

However, a disadvantage is that the grounding of the active conductor is often associated with additional organizational and technical effort, as the ground connection must be made manually by a qualified electrician. A more efficient technical solution which reduces the number of recurring interventions in the circuit distributor (distribution cabinet) would be particularly desirable in medical facilities, such as hospitals.

### SUMMARY

The object of the invention at hand is therefore to design a measuring arrangement and a measuring method for measuring a loop impedance in an ungrounded power supply system, which reduce both the circuitry-related effort and the additional organizational effort of the measurement and in particular make recurring manual interventions in the circuit distribution avoidable.

This task is attained using a measuring arrangement in that a controlled grounding device is disposed between the active conductors and the protective ground at a feeding point of the ungrounded power supply system and switches the grounding of one of the active conductors, and in that a unidirectional communication channel is formed between an extended measuring device and the grounding device, control information being transmitted from the extended measuring device to the grounding device via the communication channel in order to control the grounding device.

The fundamental idea of the present invention is therefore to dispose a controlled grounding device on the feeding side in the immediate vicinity of the power source (feeding point—in the AC system the line transformer) between the active conductors and the protective conductor. This grounding device is designed such that it selectively overrides one of the active conductors to ground on the feeding side according to the control information received by the measuring device via the communication channel and forms a residual current loop, whose loop impedance can be measured, by interacting with the extended measuring device disposed on the consumer side. Manual grounding on site is therefore not necessary.

In this context, the control information is generated by the extended measuring device connected to a consumer point on the consumer side and telecommunicated to the grounding device.

This provides an automated technical solution for measuring the loop impedance in ungrounded power supply systems, which makes prior manual grounding of the IT network obsolete and at the same time is based on a reliable, normatively specified and therefore recognized measurement method.

In a further embodiment, the communication channel is formed by the residual current loop, a modulated residual current, which transmits the control information, flowing in the residual current loop.

The installed infrastructure in the form of the active conductors and the protective conductor of the ungrounded power supply system is advantageously used as a communication channel for unidirectional transmission of the control information. The residual current loop formed by the active conductors and the protective conductor and closed via the grounding device serves as a line-bound transmission path for the control information, in which a modulated residual current flows as an information-carrying signal.

Preferably, during a setting time, the modulated residual current has the shape of a residual-current pulse sequence binary encoded by via amplitude modulation, the active conductor to be grounded being encoded in the residual-current pulse sequence as the control information.

The control information to be sent to the grounding device as to which of the active conductors is to be grounded is transmitted by modulation (amplitude modulation) of the residual current in the form of a binary-encoded residual-current pulse sequence. The corresponding switch position in the grounding device is assigned an agreed, distinctive and preferably unmistakable residual-current pulse pattern of a specific length (setting time), which is generated in the extended measuring device by switching the residual current on/off (modulation by on/off keying) and evaluated in the grounding device in order to switch the feeding-side grounding of the active conductor in question.

Unmistakable communication by means of the residual-current pulse pattern virtually eliminates the possibility of the grounding being falsely activated or triggered by constant or intermittent insulation faults.

In a further embodiment, the extended measuring device has a coupling change-over switch for the controlled overriding of one of the active conductors, a load resistance, via which the conductor-to-ground voltage is registered, a make contact for the controlled overriding of the load resistance and measuring and control electronics, the measuring and control electronics being configured to measure the conductor-to-ground voltage, to control the coupling change-over switch and the make contact, to generate and transmit the control information to the grounding device via the communication channel and to compute the loop impedance.

The extended measuring device is based on a loop measuring device with a generally known measuring method, but also has measuring and control electronics as a special extension, the measuring and control electronics being configured to automatically conduct the measuring task as intended by the invention. In particular, the measuring and control electronics controls the clocking of the make contact in order to transmit the control information in the form of the binary-encoded residual-current pulse sequence to the centrally disposed grounding device, which can be remotely controlled in this manner.

The make contact is advantageously designed as a controlled semiconductor switch.

Designing the make contact as a semiconductor switch enables the residual-current pulse sequence to be formed having a clock rate in the single-digit kHz range.

The grounding device also has: a three-way switch for grounding one of the active conductors and measuring and evaluation electronics for evaluating the modulated residual current using a measuring resistance connected between the active conductors and the protective conductor via coupling capacitors. The coupling capacitors having a capacitance in the range <<1 μF thus make it possible in an advantageous manner that an insulation monitoring device (IMD)—to be permanently connected according standard—is not impaired in its measuring function as long as no loop impedance is measured.

The three-way switch temporarily switches the ungrounded power supply system from the ungrounded state in normal operation to the grounded state by connecting one of the active conductors to the protective conductor. Which active conductor is to be grounded is determined in the measuring and evaluation electronics by evaluating the control information contained in the residual-current pulse sequence.

The measuring arrangement according to the invention as described above implements the method steps described in the independent method claim. In this respect, the aforementioned technical effects and resulting procedural advantages also apply to the process features.

In particular, the transmission of control information from the extended measuring device to a grounding device for (remote) control of the grounding device by means of a unidirectional communication channel formed between the extended measuring device and the grounding device should be emphasized.

The measuring arrangement according to the invention, consisting of the grounding device, the extended measuring device and the communication channel formed by the active conductors and the protective conductor, avoids the interventions in the central electrical distribution of the ungrounded power grid which hitherto had been necessary for loop impedance measurement. This automated measurement of the loop impedance is therefore technically more reliable and economically more efficient than a measurement with manual grounding.

Advantageously, the grounding device can be a component of an insulation monitoring device for determining the insulation resistance in an ungrounded power supply system.

An insulation monitoring device—preferably standardized—can be equipped with the described grounding device as an extension of its functionality in order to be able to measure the loop impedance in the ungrounded power supply system in addition to insulation monitoring.

### BRIEF DESCRIPTION OF DRAWINGS

Further advantageous embodiment features are derived from the following description and the drawings, which describe a preferred embodiment of the invention at hand using examples.

FIG. 1 shows a measurement of the loop impedance in an ungrounded power supply system according to the state of the art.

FIG. 2 shows a measuring arrangement according to the invention having a grounding device, an extended measuring device and a communication channel.

FIG. 3 shows a method sequence according to the invention having switch positions.

### DETAILED DESCRIPTION

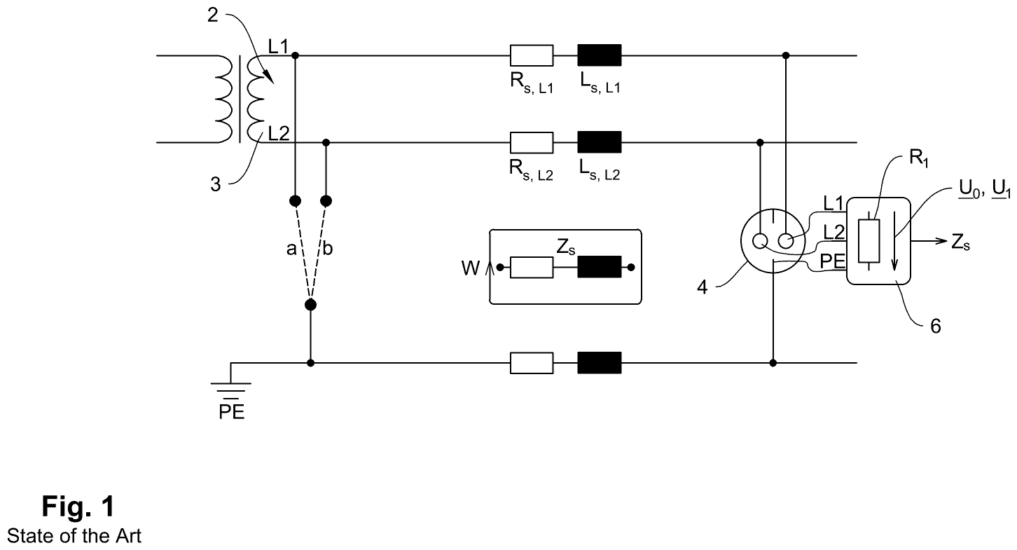

FIG. 1 shows, as state of the art, the general measurement setup for measuring the loop impedance Zₛ according to VDE 0100-600 (IEC 60364-6) using a measuring device 6 according to DIN EN 61557-3 (IEC 61557) in an ungrounded power supply system 2.

The ungrounded power supply system 2 is exemplarily configured as an AC network having a network transformer at a feeding point 3 and two active conductors L1 and L2, each of which has a line impedance having a line resistance R_{s, L1}, R_{s, L2} and a line inductance L_{s, L1}, L_{s, L2}.

In addition to the connection to the active conductors L1, L2, a consumer point 4 (socket outlet) has a connection of the protective conductor PE, via which the conductive housings of the consumers connected to the IT network are grounded.

As all active parts of the ungrounded power supply system 2 are electrically isolated from the protective conductor PE by definition, a bridge must be set at point a or b on the supply side to measure the loop impedance Zₛ, i.e., one of the active conductors L1, L2 must be grounded, whereby the IT network 2 is connected to the protective conductor PE at the feeding point 3. Only after this closed (fault) current loop W has been formed, is it possible to conduct a measurement using a conventional measuring device 6 connected to the consumer point 4 by means of the voltage reduction method including measurement of the conductor-to-ground voltage U₀ (in the unloaded case) and U₁ (in the loaded case).

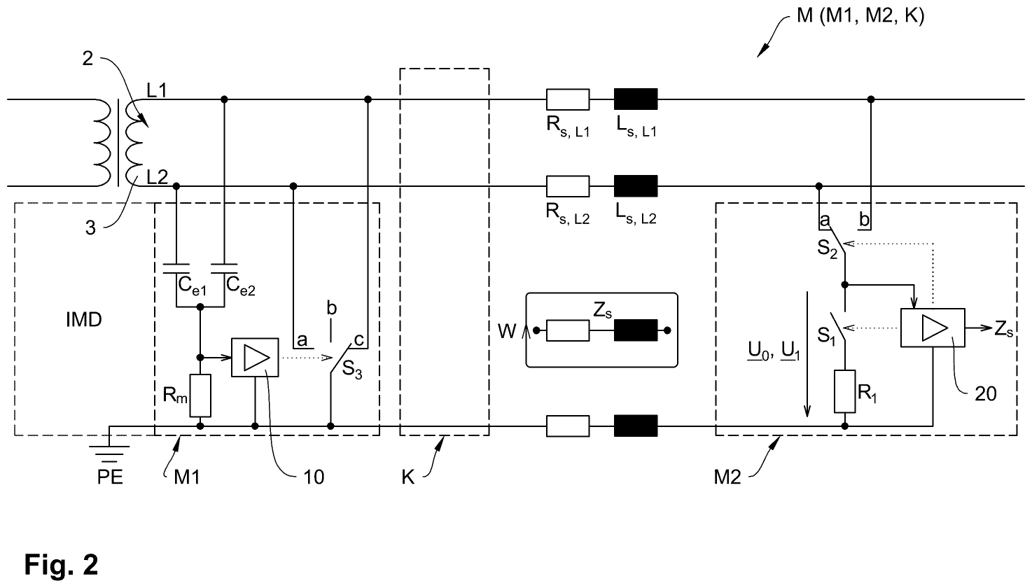

FIG. 2 shows a measuring arrangement M (M1, M2, K) according to the invention for measuring in the ungrounded power supply system 2.

The measuring arrangement M comprises as essential elements a grounding device M1, an extended measuring device M2 and a communication channel K.

According to the invention, the active conductors L1, L2 and the protective conductor PE serve as the communication channel K for transmitting the control information from the extended measuring device M2 to the grounding device M1.

The grounding device M1 comprises a three-way switch S₃ for grounding one of the active conductors L1, L2; measurement and evaluation electronics 10 for evaluating the modulated residual current; and a measuring resistance Rₘ connected between the active conductors L1, L2 and the protective conductor via coupling capacitors Cₑ₁, Cₑ₂.

In normal operation, the three-way switch S3 is in position b, meaning the ungrounded power supply system 2 is not grounded by definition. Controlled by the measurement and evaluation electronics 10, the three-way switch S3 can optionally establish a grounding between L1 and PE (position c) or L2 and PE (position a).

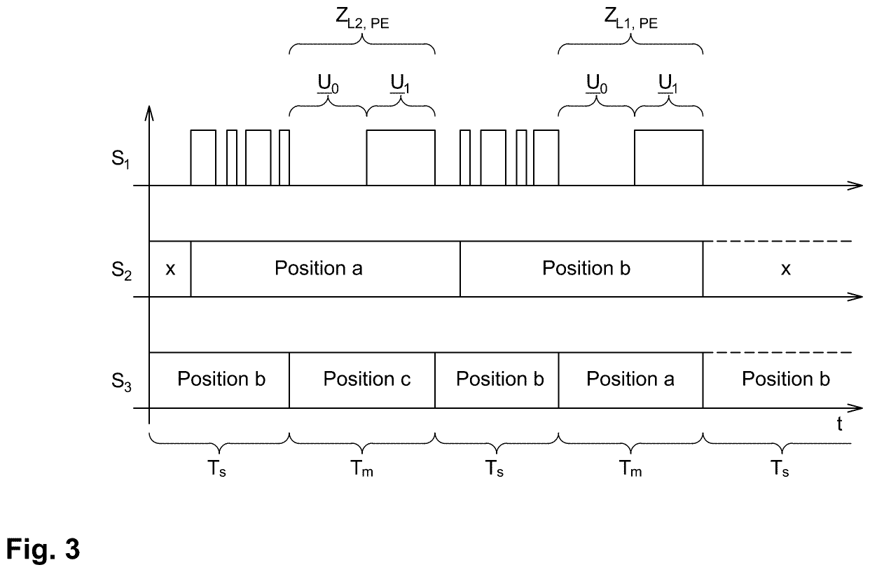

The measurement and evaluation electronics 10 are connected to the ungrounded IT network 2 via coupling capacitors Cₑ₁, Cₑ₂ having small capacitance values (Ce1, Ce2<<1 μF) and a measuring resistance Rₘ. During a setting time Tₛ (FIG. 3), the voltage dropping across the measuring resistance Rₘ is first measured in position b of the three-way switch S₃ in order to decode the modulated residual current, i.e., the binary-encoded residual-current pulse sequence. The three-way switch S3 then switches the active conductor L1 or L2 specified by the extended measuring device M2 to ground and the actual loop impedance measurement can be conducted.

With regard to realizing the measurement functions for an ungrounded power supply system 2 as compactly as possible, the grounding device M1 can be integrated into an insulation monitoring device IMD.

The extended measuring device M2 comprises a coupling change-over switch S2, a load resistance R₁, a make contact S1 and measuring and control electronics 20 and can be designed as a stationary device or as a mobile, portable device having a plug connection.

The coupling change-over switch S2 having positions a and b is used for a controlled overriding of one of the active conductors L1, L2. The measuring and control electronics 20 thus determines at which of the active conductors L1, L2 the loop impedance Zₛ is to be measured.

The load resistance R₁ is connected to the make contact S1. The make contact S1 is also capable of clocking up to the single-digit kHz range and thus generating the modulated residual current in the form of the binary-encoded residual-current pulse sequence. For this purpose, the make contact S1 is preferably designed as a semiconductor switch.

The coupling change-over switch S2 and the three-way switch S3 can be either electromechanical or semiconductor-based.

The load resistance R₁ is used to register the conductor-to-ground voltage U₁ under load, i.e., when the make contact S1 is closed. The load resistance R₁ is dimensioned such that a current in the single-digit ampere range flows in the residual current loop W at a nominal network voltage of 230 V, for example.

The conductor-to-ground voltage U₀ in the unloaded case is registered via the open make contact S1 to ground PE.

The measurement of the corresponding conductor-to-ground voltage U₀ (open-circuit voltage in the unloaded case, corresponds to the network nominal voltage) and U₁ (network voltage in the resistively loaded case) as well as the computations for determining the loop impedance Zₛ are conducted in the measuring and control electronics 20.

The measuring and control electronics 20 is also used to control the coupling change-over switch S2 and, by controlling the make contact S1, to generate and transmit the control information via the communication channel K to the grounding device M1.

FIG. 3 shows a method sequence according to the invention having switch positions of the make contact S1, the coupling change-over switch S2 and the three-way switch S3. The switch positions and the idea of the invention are illustrated, the modulation of the residual current corresponding to the switch position of the make contact S1 is shown in a highly simplified form for graphical reasons.

In principle, the measuring method according to the invention can be described in such a manner that the extended measuring device M2 requests the grounding of one of the active conductors L1, L2 from the grounding device M1 (setting time Tₛ); this grounding is established for a short period of time (measuring duration Tₘ); and the measurement is conducted within this measuring duration Tₘ using the known method of voltage reduction according to the above equation. The time span should cover a few network voltage periods, for example 10 periods, i.e., 200 ms, for a 50 Hz network. With a lower load current, the duration can be extended to a single-digit number of seconds in order to improve the signal-to-noise ratio.

The method sequence is designed in detail such that the extended measuring device M2 is set to the residual current loop W to be measured—via the active conductor L2 (position a) or the active conductor L1 (position b)—by means of the coupling change-over switch S2 and modulates the residual current during the setting time Tₛ by means of the make contact S1 controlled by the measuring and control electronics 20 and the load resistance R₁. The modulation takes place in the form of a binary-encoded residual-current pulse sequence, which contains the information regarding which of the active conductors L1, L2 is to be grounded.

The binary-encoded residual-current pulse sequence has a sufficiently high clock rate so that clear and distinguishable control information can be transmitted and decoding in the receiver (grounding device M1) is as error-free as possible.

During the transmission of the control information—in position b of the three-way switch S3 in the grounding device M1—the current loop closed via the coupling capacitors Cₑ₁, Cₑ₂ and the measuring resistance Rₘ comes into effect. The current flowing in this current loop causes a voltage to drop across the measuring resistance Rₘ in time with the binary-encoded residual-current pulse sequence, the voltage being detected by the measurement and evaluation electronics 10. The information is evaluated here and the three-way switch S3 is switched to position a or c in accordance with the request for the actual measurement, thus establishing the ideal grounding of the active conductor L2 or L1 at the feeding point 3.

After the setting time Tₛ has elapsed, the make contact S1 is opened and the open-circuit voltage U₀ is measured, then the make contact S1 is closed and the voltage under load U₁ is measured.

Once the measurement has been completed, the three-way switch S3 of the grounding device M1 automatically returns to position b and the ungrounded state of the power supply system 2 is restored.

The method according to the invention is not limited to use in conjunction with the ungrounded power supply system 2 shown here and having an AC supply and two active conductors L2, L1. The application shown here represents an exemplary embodiment and the claimed method and its implementation in the measuring arrangement can in principle also be used in multiphase AC networks and DC networks. However, a 4-way switch in the grounding device M1 and a 3-way switch in the extended measuring device M2 are required for installation in 3AC systems.

1. A measuring arrangement (M (M1, M2, K)) for measuring a loop impedance (Zₛ) of a residual current loop (W) formed by an active conductor (L1, L2) and a protective conductor (PE) in an ungrounded power supply system (2), the measuring arrangement (M (M1, M2, K)) having a measuring device (6) connected to a consumer point (4) and serving to measure a conductor-to-ground voltage (U₀, U₁) and to compute the loop impedance (Zₛ), characterized in that a controlled grounding device (M1) is disposed between the active conductors (L1, L2) and the protective ground (PE) at a feeding point (3) of the ungrounded power supply system (2) and switches the grounding of one of the active conductors (L1, L2), and in that a unidirectional communication channel (K) is formed between an extended measuring device (M2) and the grounding device (M1), control information being transmitted from the extended measuring device (M2) to the grounding device (M1) via the communication channel (K) in order to control the grounding device (M1).

2. The measuring arrangement (M) according to claim 1, wherein the communication channel (K) is formed by the residual current loop (W), a modulated residual current, which transmits the control information, flowing in the residual current loop (W).

3. The measuring arrangement (M) according to claim 2, wherein, during a setting time (Tₛ), the modulated residual current has the shape of a residual-current pulse sequence binary encoded by via amplitude modulation, the active conductor to be grounded being encoded in the residual-current pulse sequence as the control information.

4. The measuring arrangement (M) according to claim 1, wherein the extended measuring device (M2) has a coupling change-over switch (S2) for the controlled overriding of one of the active conductors (L1, L2), a load resistance (R₁), via which the conductor-to-ground voltage (U₀, U₁) is registered, a make contact (S1) for the controlled overriding of the load resistance (R₁) and measuring and control electronics (20), the measuring and control electronics (20) being configured to measure the conductor-to-ground voltage (U₀, U₁), to control the coupling change-over switch (S2) and the make contact (S1), to generate and transmit the control information to the grounding device (M1) via the communication channel (K) and to compute the loop impedance (Zₛ).

5. The measuring arrangement (M) according to claim 4, wherein the make contact (S1) is designed as a semiconductor switch.

6. The measuring arrangement (M) according to claim 1, wherein the grounding device (M1) has a three-way switch (S3) for grounding one of the active conductors and measuring and evaluation electronics (10) for evaluating the modulated residual current using a measuring resistance (Rₘ) connected between the active conductors (L1, L1) and the protective conductor (PE) via coupling capacitors (Cₑ₁, Cₑ₂).

7. An insulation monitoring device (IMD) for determining the insulation resistance in an ungrounded power supply system (2) including the grounding device (M1) according to claim 1.

8. A measuring method for measuring a loop impedance (Zₛ) of a residual current loop (W) formed by an active conductor (L1, L2) and a protective conductor in an ungrounded power supply system (2), the method comprising the following steps:
measuring a conductor-to-ground voltage (U₀, U₁) and computing the loop impedance (Zₛ) by means of an extended measuring device (M2) connected to a consumer point (4),
wherein the grounding of one of the active conductors (L1, L2) is switched by means of a controlled grounding device (M1) disposed at a feeding point (3) of the ungrounded power supply system between the active conductors and the protective conductor, and in that control information is transmitted to the grounding device (M1) from the extended measuring device (M2) by means of a unidirectional communication channel (K) formed between the extended measuring device (M2) and the grounding device (M1) in order to control the grounding device (M1).

9. The measuring device according to claim 8, wherein the control information is transmitted by a modulated residual current which flows in the residual current loop (W) forming the communication channel (K).

10. The measuring method according to claim 9, wherein the modulated residual current is transmitted as a binary-encoded residual-current pulse sequence during a setting time (Tₛ), the active conductor (L1, L2) to be grounded being encoded in the residual-current pulse sequence as control information.

11. The measuring method according to claim 8, further including a controlled overriding of one of the active conductors (L1, L2) by means of a coupling change-over switch (S2) of the extended measuring device (M2), a detection of the conductor-to-ground voltage (U₀, U₁) via a load resistance (R₁) in the extended measuring device (M2), a controlled overriding of the load resistance (R₁) by means of a make contact (S1) of the extended measuring device (M2), a measurement of the conductor-to-ground voltage (U₀, U₁) by means of measuring and control electronics (20) of the extended measuring device (M2), a control of the coupling change-over switch (S2) and the make contact (S1), a generation and transmission of the control information by means of the measuring and control electronics (20), and a computation of the loop impedance (Zₛ) by means of the measuring and control electronics (20).

12. The measuring method according to claim 11, wherein the load resistance (R₁) is overridden by means of a make contact (S1) designed as a semiconductor switch.

13. The measuring method according to claim 8, further including a grounding of one of the active conductors (L1, L2) by means of a three-way switch (S3) of the grounding device (M1), an evaluation of the modulated residual current by means of measuring and evaluation electronics (10) using a measuring resistance (Rₘ) connected via coupling capacitors (Cₑ₁, Cₑ₂).
